(19) United States
(12) Patent Application Publication
(10) Pub. No.: US 2013/0164895 A1
(43) Pub. Date: Jun. 27, 2013

(54) Trench-Gated Power Devices with Two Types of Trenches and Reliable Polycidation

(71) Applicant: MaxPower Semiconductor, Inc., Santa Clara, CA (US)

(72) Inventors: Jun Zeng, Torrance, CA (US); Mohamed N. Darwish, Campbell, CA (US)

(73) Assignee: MAXPOWER SEMICONDUCTOR, INC., Santa Clara, CA (US)

(21) Appl. No.: 13/709,281

(22) Filed: Dec. 10, 2012

Related U.S. Application Data
(60) Provisional application No. 61/569,509, filed on Dec. 12, 2011.

(51) Int. Cl. H01L 29/78

(52) U.S. Cl. CPC H01L 29/7827
USPC 438/270

(57) ABSTRACT

Methods and systems for power semiconductor devices and structures with silicide cladding on both gates and field plates. Sidewall spacers, e.g. of silicon nitride, avoid lateral shorts or leakage between the gate silicide and the source region. A source metallization makes lateral contact to the shallow n++ source, and also makes contact to the field plate silicide and the p+ body contact region.

### CROSS-REFERENCE

Priority is claimed from 61/569,509 filed Dec. 12, 2011, which is hereby incorporated by reference.

### BACKGROUND

The present application relates to power MOSFETs, and more particularly to power MOSFETs having trench gate electrodes and recessed field plate trenches, and more particularly to such devices in which a silicide/polysilicon stack provides a recessed trench gate electrode.

Note that the points discussed below may reflect the hindsight gained from the disclosed inventions, and are not necessarily admitted to be prior art.

In many power MOSFETs, high switching frequencies are necessary, and it is desirable to minimize the switching power loss, which is governed by device capacitance, gate charges, and gate equivalent spreading resistance.

However, the gate equivalent spreading resistance increases significantly as the trench gate electrode becomes shallower. This is inconvenient, because shallow trench gate electrodes are used in several useful recently disclosed trench MOSFET structures. Many of these structures use a Recessed and Embedded Field Plate (RFP and EFP) with thick bottom oxide or split gate electrode. FIG. 4 shows an example of an embedded field plate structure, as shown, for example, in U.S. Pat. No. 8,076,719, which is commonly owned and has identical inventorship to the present application. The '719 patent disclosed a power MOSFET with recessed field plates and shield structure to provide a very short channel region for further reducing the gate-source capacitance and the gate-drain capacitance. The total gate charge (Q_{g}) and the Miller charge (Q_{gd}) are lowered significantly with a lower specific on-resistance (on resistance area product Rₛₚ). FIGS. 1B and 1C show other examples of split gate trench MOSFETs using recessed RFP and embedded EFP structures.

In FIGS. 1A-1C, notice that the height of the shallow gate poly can be less than the total height of the field plate poly. This is because the bottom gate oxide (marked BOX) and split gate electrode are thick to reduce gate-drain capacitance, which reduces switching speed. However, this means that the gate electrode itself, which is likely a buried mesh or array, has a higher sheet resistance, and therefore RC time delays will be present for gate electrodes which are farther from the location where connection is made to that mesh.

The techniques disclosed thus far for reducing total gate charge and Miller charge reduce the thickness of the trench gate poly. This increases gate equivalent spreading resistance R_{g}, and in turn limits the improvement to switching speed attainable by these methods. The simulation data shown in FIG. 2 illustrates an example of this relation.

### SUMMARY

The present inventors have realized that attempts to silicide gates in an RFP or EFP dual-trench structure can result in leakage or gate to source shorts at the edges of the gates, as shown in FIG. 3. This is because of the time, temperature, and reactivity conditions during the formation and anneal of the metal silicide cladding.

The present application presents improved polycidation methods and structures in trench-gated power MOSFETs with trench gate electrodes and recessed field plate trenches. A silicide/polysilicon stack provides a shallow trench gate electrode such as a split gate or recessed trench gate electrode, which has a vertical extent which can be much shorter than the vertical extent of the field plate electrodes. This improved silicidation allows the use of silicidation processes in such devices while minimizing the associated risk of shorts.

The disclosed innovations, in various embodiments, provide one or more of at least the following advantages. However, not all of these advantages result from every one of the innovations disclosed, and this list of advantages does not limit the various claimed inventions.
A deep-trench two-trench structure that has a very low sheet resistance in the buried gate electrode structure
Synergy with the short vertical extent of the gate in a device like that of FIG. 4
Low sheet resistance
Uniform turn-on and turn-off

### BRIEF DESCRIPTION OF THE DRAWINGS

The disclosed inventions will be described with reference to the accompanying drawings, which show important sample embodiments and which are incorporated in the specification hereof by reference, wherein:

FIGS. 1A, 1B, and 1C show some sample embodiments of novel implementations of the present inventions.

FIG. 2 shows simulation data.

FIG. 3 shows a flawed hypothetical structure.

FIG. 4 shows a previous structure.

FIGS. 5A, 5B, 6, 7, 8, and 9 show one sample process flow that can be used to implement the present inventions.

FIGS. 10, 11, and 12 show another sample process flow that can be used to implement the present inventions.

FIG. 13 shows another sample embodiment of the present inventions.

FIG. 14 shows another sample embodiment of the present inventions.

FIG. 15 shows another sample embodiment of the present inventions.

FIG. 16 shows another sample embodiment of the present inventions.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

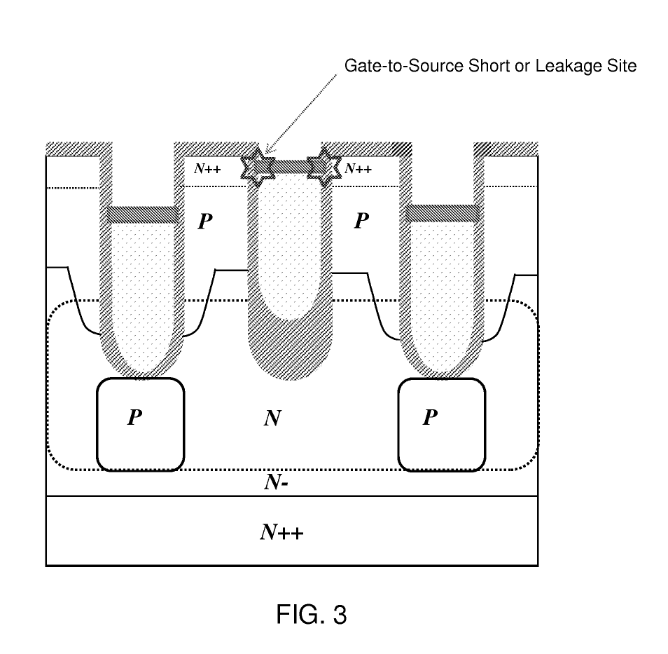

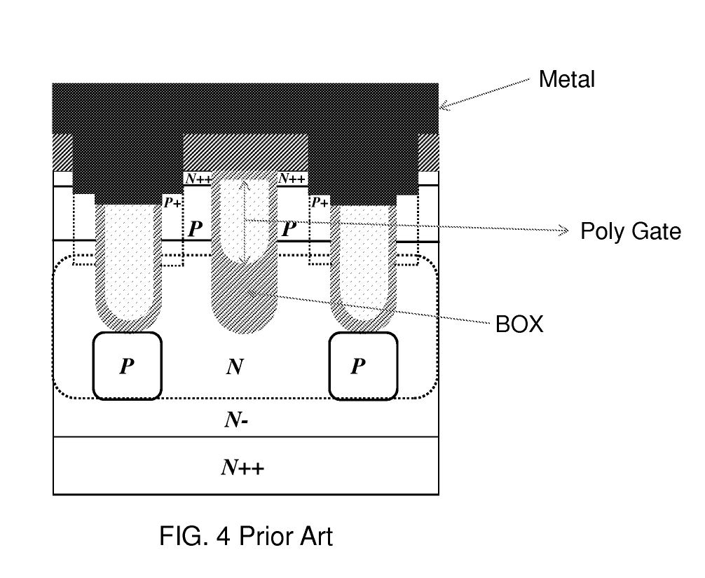

The present inventors have realized that attempts to silicide gates in shallow trench gate electrode such as an RFP or EFP dual-trench or split gate structures can result in leakage or shorts at the edges of the gates, as shown in FIG. 3. This is because of the time, temperature, and reactivity conditions during the formation and anneal of the metal silicide cladding.

The present application presents improved polycidation methods and structures in trench-gated power MOSFETs with trench gate electrodes and recessed field plate trenches. A silicide/polysilicon stack provides a recessed trench gate electrode, which has a vertical extent which can be much shorter than the vertical extent of the field plate electrodes. This improved silicidation allows the use of silicidation processes in such devices while minimizing the associated risk of shorts.

After trench structures have been formed, e.g. by depositing polysilicon to form gate electrodes, sidewall insulator filaments are introduced at the sidewalls of the trenches, to produce a spacer element between the gate oxide and the polycide layer. This provides a stress-relieving buffer layer to reduce the risk of shorts resulting from the polycidation process. These sidewall filaments can be formed from, e.g., a nitride layer, such as SiN, over a pad oxide layer, such as PE-SiO₂.

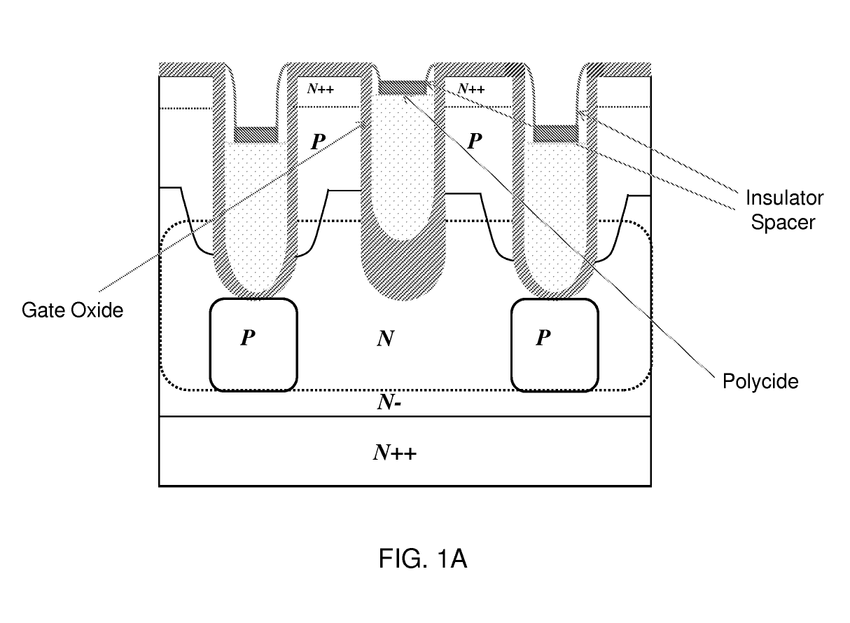

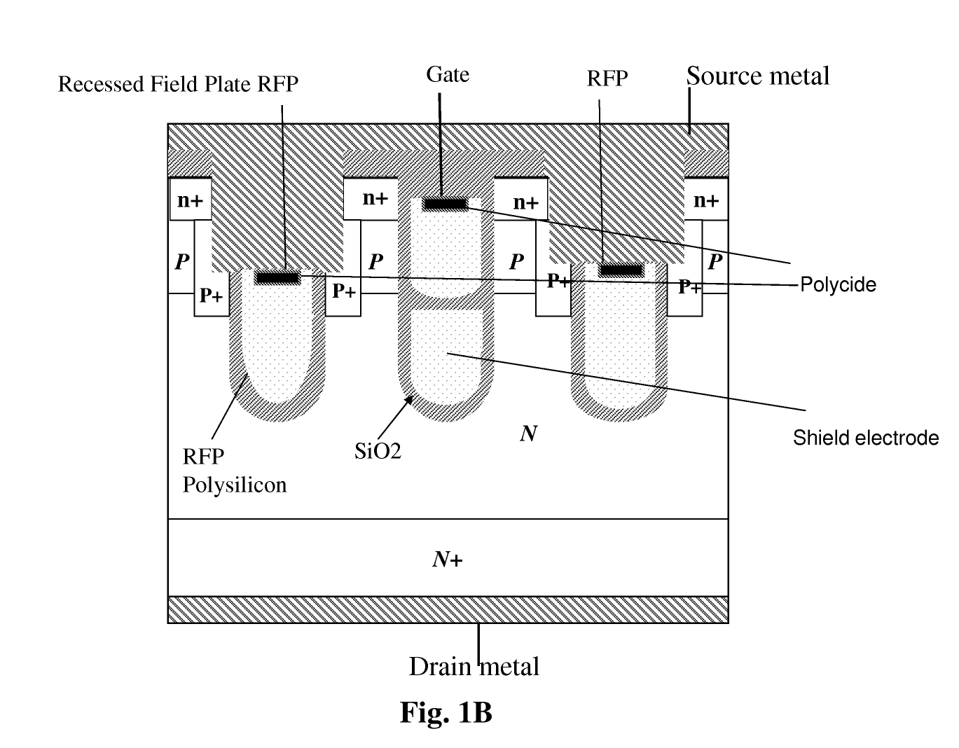

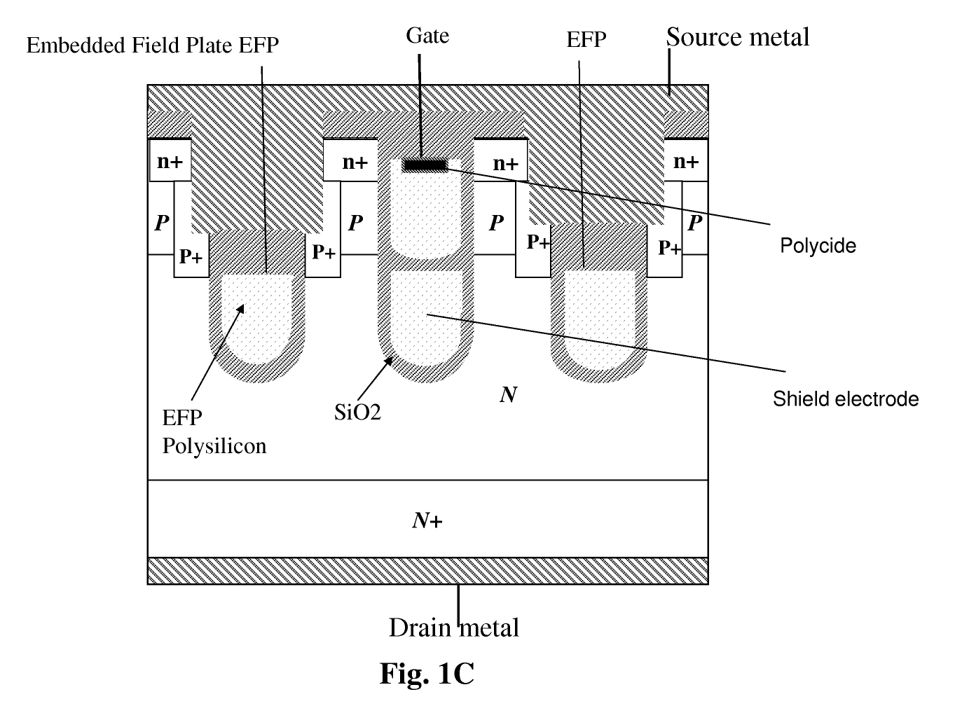

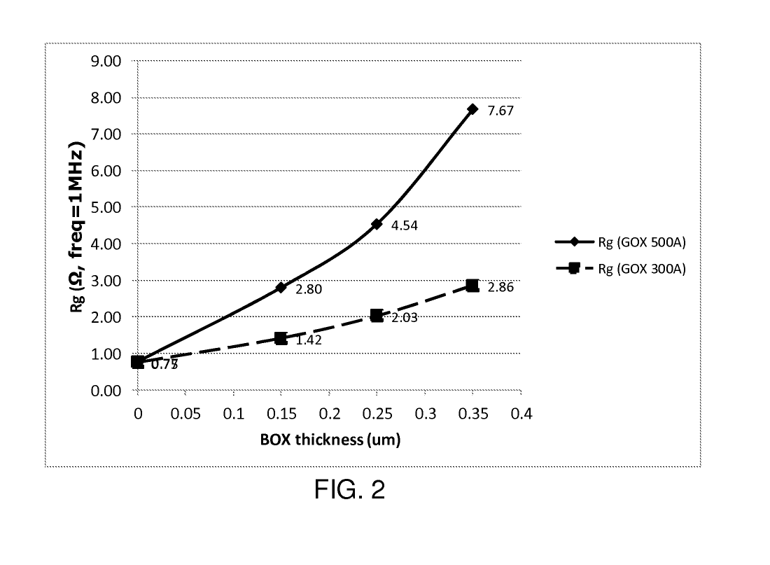

Using a siliciding technique as in FIG. 1A results in a gate electrode which has silicide cladding, and thus less sheet resistance. Less RC time delay is therefore distributed among the gates in the gate mesh, without the leakage risks and damage to gate oxide shown in FIG. 3. Note that the damage shown in FIG. 3 is a damage to the gate oxide layer. This thin oxide is a critical layer, and damage in the N+ source region increases the risk that damage might affect operation of the basic MOS-gate capacitance where the gate is coupled to the body.

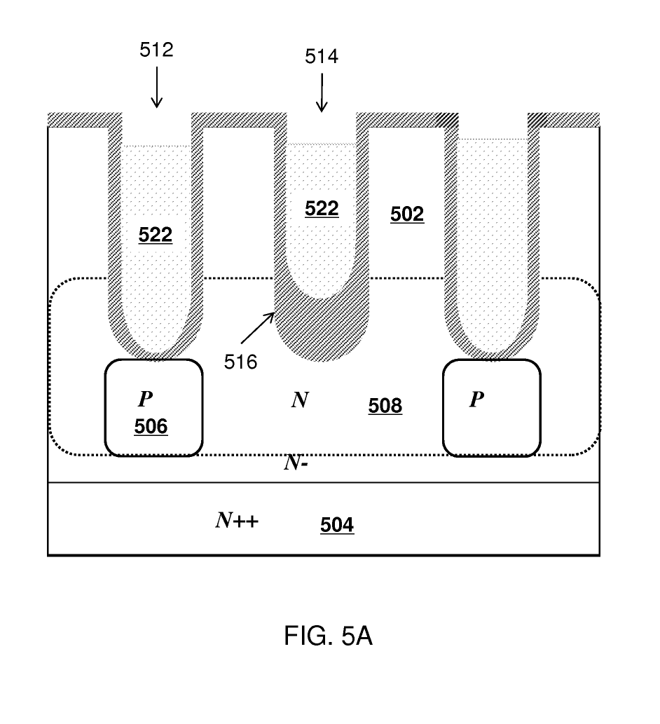

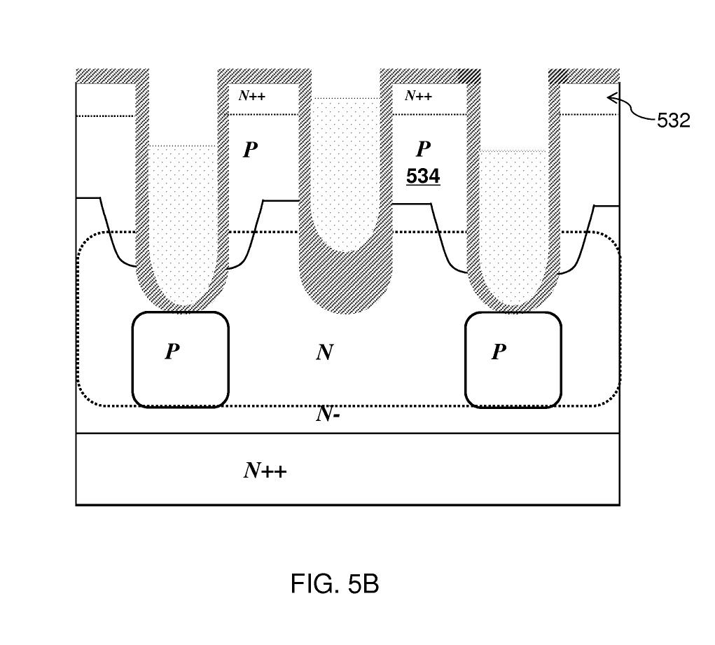

FIGS. 5A and 5B show a process flow for implementing the claimed inventions. FIG. 5A shows an initial state, where an N on N+ epitaxial wafer has been etched with trenches, which will later become both gate trenches and embedded silicided field plate (ESFP) trenches. In this example, an acceptor implant has been made through the bottom of the field plate trenches to form P regions below the bottoms of these trenches. These p regions help to shape the isopotential contours in the off state, to thereby increase the breakdown voltage. This structure is described in detail in U.S. Pat. No. 8,076,719.

Fabrication begins with N-type epitaxial layer 502 over N++ substrate 504. P type regions 506 are formed below the field plate trenches 512 by implantation through the bottoms of the field plate trenches 512.

In this example, an N-type doping-enhanced region 508 has also been created at depths which are preferably below the depth of the gate electrode. As discussed in the '719 patent, this further exploits the effect of the deep P type regions 506 to provide better breakdown voltage—on state conductivity tradeoff. Note that both trenches have been etched, but the gate trenches 514, unlike the field plate trenches 512, have a thick oxide region 516 at the bottoms in this example. This reduces parasitic gate-to-drain capacitance, and avoids excess voltage stress appearing across the gate oxide 518.

In this example, both the field plate trenches 512 and the gate trenches 514 have been filled with undoped polysilicon. In this example, the polysilicon has been deposited to a thickness of 600 nm. An implant of P31 is then performed, e.g. at an area dose of 2.7×10¹⁶ cm⁻², to bring the polysilicon to a heavily-doped N type state, to improve its conductivity. After this implant, a drive step is then preferably performed, e.g. 30 minutes at 920° C. At this point a mask can be used if desired to pattern the polysilicon, but this is not used in all implementations.

After this, the first polysilicon layer 522 is etched back uniformly, with an etch distance (below silicon surface) of, e.g., 150-200 nm. At this point the silicon surface retains, e.g., 30 nm of thickness of high-quality SiO₂.

FIG. 5B shows a further stage of processing in the structure of FIG. 5A. At this point a masked donor implant has been used to create N-type source regions 532. The source regions can be created, for example, by implantation of As, e.g. at an area dose of 4×10¹⁵ cm⁻². This can optionally be performed as a two-step implant to provide vertical uniformity. Another mask is now used to define the locations of the field plate trenches 512, and a second polysilicon etch is performed in accordance with this mask pattern. At this point a P well implant is performed, and an activation step follows, e.g. annealing at 950° C. for 30 minutes. This forms a P type region 534 which will provide the body region for the transistor device.

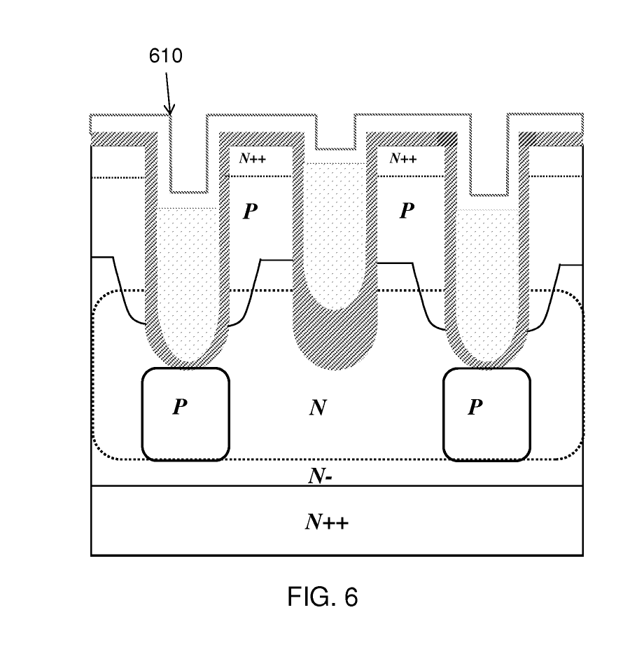

The process through this point has been conventional, but inventive modifications are now introduced, as shown in FIG. 6.

FIG. 6 shows a further stage of processing of the same structure as is shown in FIGS. 5A and 5B. In this example, a plasma enhanced silicon dioxide (PE-SiO₂) deposition has been performed to a thickness of e.g. 10 nm. This provides a stress-relieving buffer layer between the ensuing silicon nitride and the underlying semiconductor material. Pyrolytic SiN deposition can be performed, e.g. at 750° C., to a thickness of e.g. 800 Å.

This is a conformal deposition, which provides a conformal layer 610 of SiN both on the sidewalls of the trench recess areas, and also over the planar field area. Note that the recess is shallower in the gate trenches 514 than in the field plate trenches 512. Since the field plate trenches 512 have a deeper recess than the gate trenches 514, the vertical extent of the SiN on the field plate trenches 512 is greater than that of the gate trenches 514.

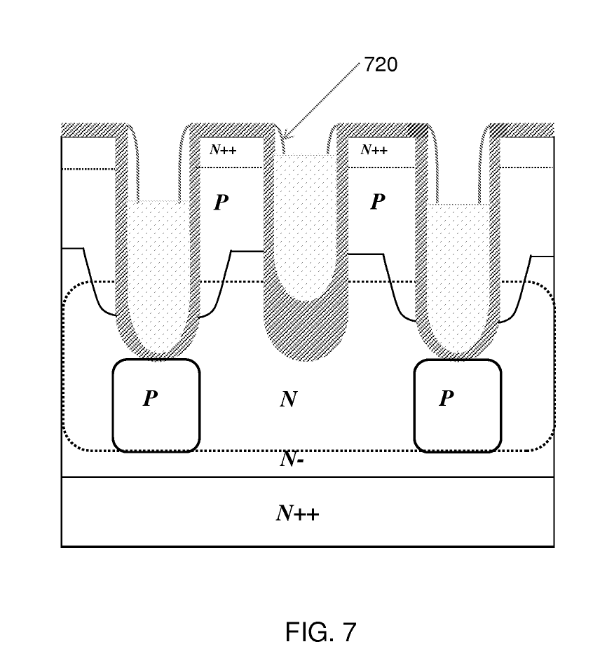

FIG. 7 shows a further stage in this process flow. At this point, SiO₂ and SiN anisotropic etchback has been performed. The last stage of this etch process is selected so that it will stop on polysilicon. This results in nitride sidewall filaments (also known as sidewall spacers) 720 both in the gate trenches 514 and in the field plate trenches 512.

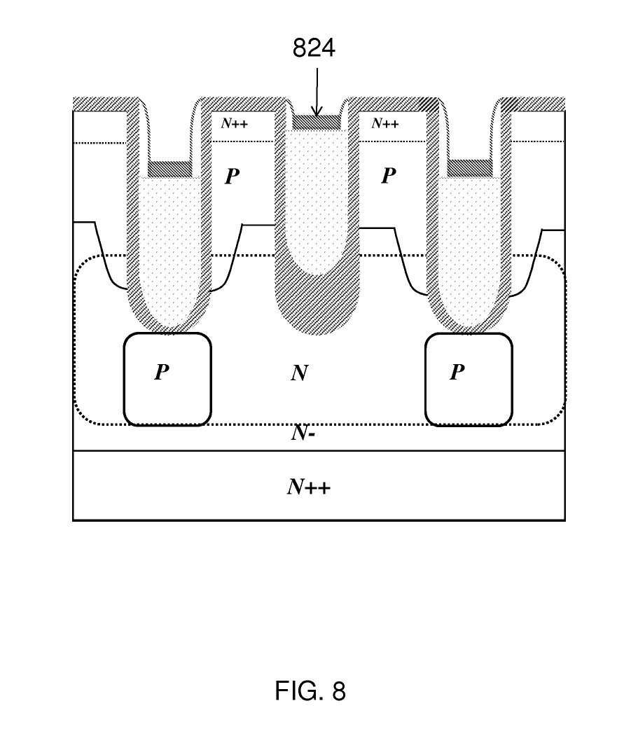

FIG. 8 shows a further stage in processing. At this point a silicide source metal, e.g. Ti, has been deposited. In this specific process example, Ti is deposited at this point, to a thickness in the range of, e.g., 10-100 nm. A first rapid thermal annealing (RTA) step is then performed at a temperature of e.g. 600° C. At this point the unreacted Ti metal is removed, e.g. by CMP planarization followed by an etch back, which leaves a reacted silicide layer 824 in place both in the gate trenches 514 and in the field plate trenches 512.

After the nonreacted Ti has been removed from planar surfaces, a second rapid thermal anneal step is performed, e.g. to 900° C. This improves the quality of the silicide, and results in a better sheet resistance for the silicide layer. After this the remainder of the unreacted metal, in this example, is removed.

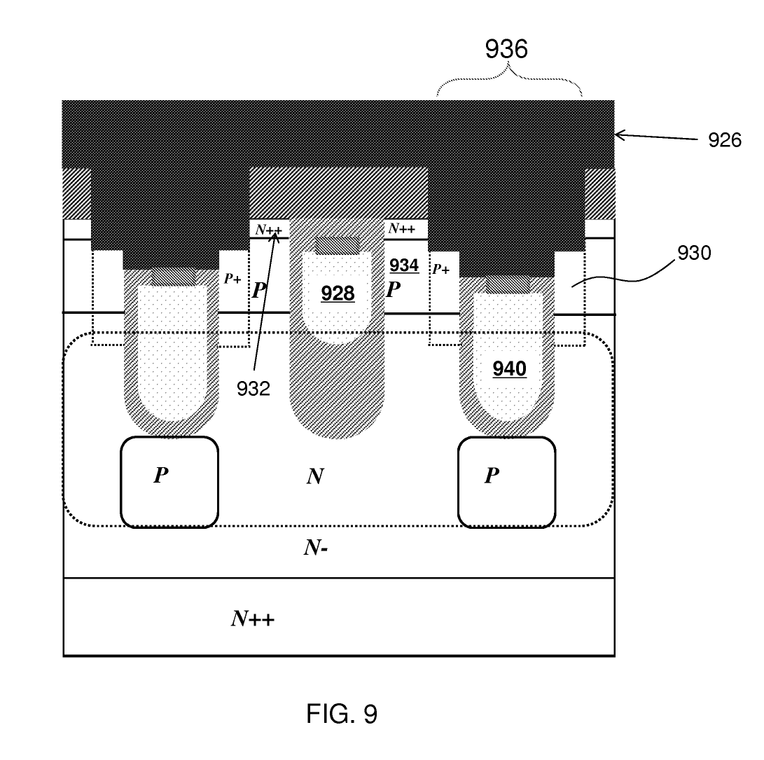

FIG. 9 shows a further stage in processing. A patterned etch has been used to remove the nitride and oxide from the field plate trenches 512, and a new patterned etch has been used to cut wide recesses over the tops of the field plate trenches 512. This results in field plate contact openings into which a metallization layer 926 is deposited. This metallization 926 provides connection to field plates in many areas. Note that this metallization makes contact to the polysilicon field plate electrode 940 through the silicide cap layer 824. Note that the gate electrode 928 also has a silicide cladding layer on top of it. The connection to the gate electrode occurs out of the plane (or outside of the area) of this drawing, and is not visible in this figure. Note that after the wider opening 936 has been cut over the field plate trenches 512, a P+ implant is performed. This forms the P+ body contact regions 930. These body contact regions provide ohmic contact for the metallization layer 926, and therefore provide a low-resistance connection to the body region 934. Thus in the same location the metallization 926 forms connection to the N+ source layer 932, the body region 934, and the field plate electrodes 940.

FIGS. 1B and 1C show two alternative embodiments where the silicide layer is recessed into the polysilicon material. Each of these structures can be fabricated using process flows similar to the methods of FIGS. 5-8. The starting structures for each of FIG. 1B and FIG. 1C differ from those seen in FIGS. 5A and 5B, for example in that the gate is a split gate electrode in each of FIGS. 1B and 1C. Process flows are modified accordingly, e.g. to replace recessed field plates with embedded field plates in FIG. 1C. Before processing steps like those of e.g. FIGS. 6-8, a brief etch is performed to produce appropriate recesses in the poly where the silicide is subsequently formed. These added recesses modify the P body and P+ body contact doping profiles.

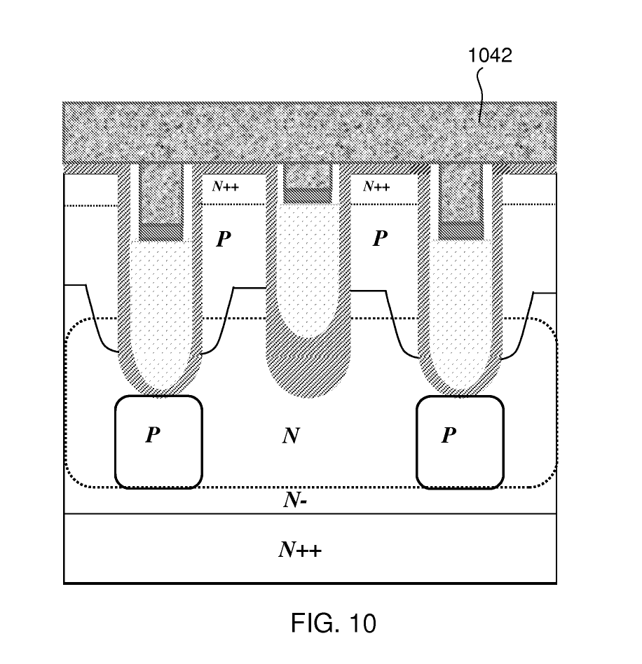

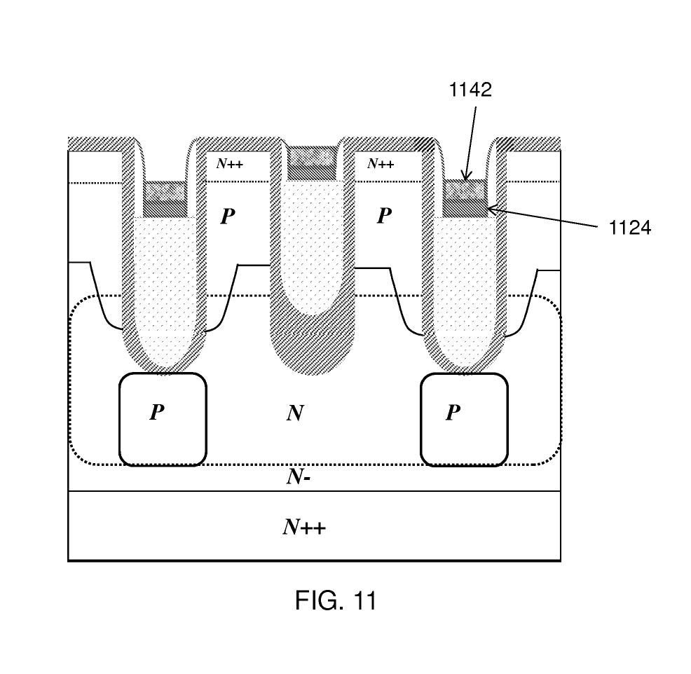

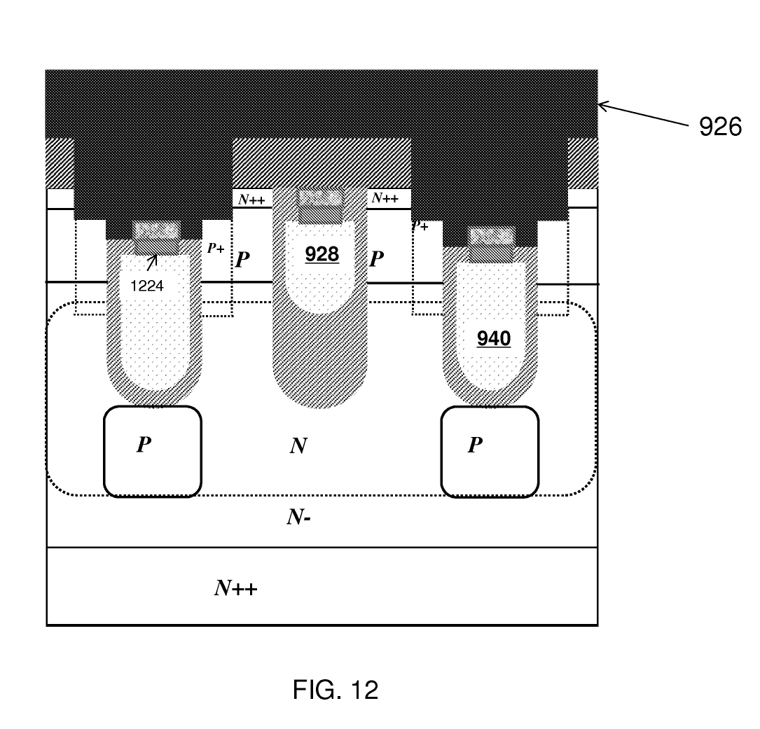

FIG. 10 shows an alternative embodiment where the unreacted siliciding metal 1042 (Ti in this example) is only partially removed, to form an intermediate structure as shown in FIG. 11. In this example, the cladding layers 1124 also include an overlying layer of unreacted metal 1142. This unreacted metal then, as shown in FIG. 12, provides a further link in the connection between metallization 926 and the field plate 940. This additional metallization also forms an element of the cladding 1224 for the gate electrode 928.

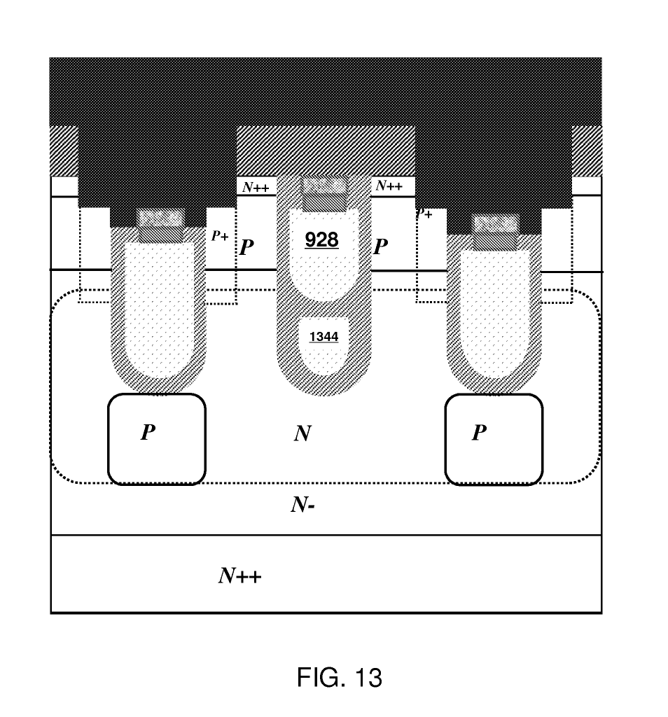

FIG. 13 shows a further alternative embodiment, in which a shield electrode 1344 underlies the gate electrode 928. Other features of this implementation can be the same as those in FIG. 9 or 11, and modifications and variations as discussed below can be performed on this embodiment as well as on the embodiments of FIGS. 9 and 11.

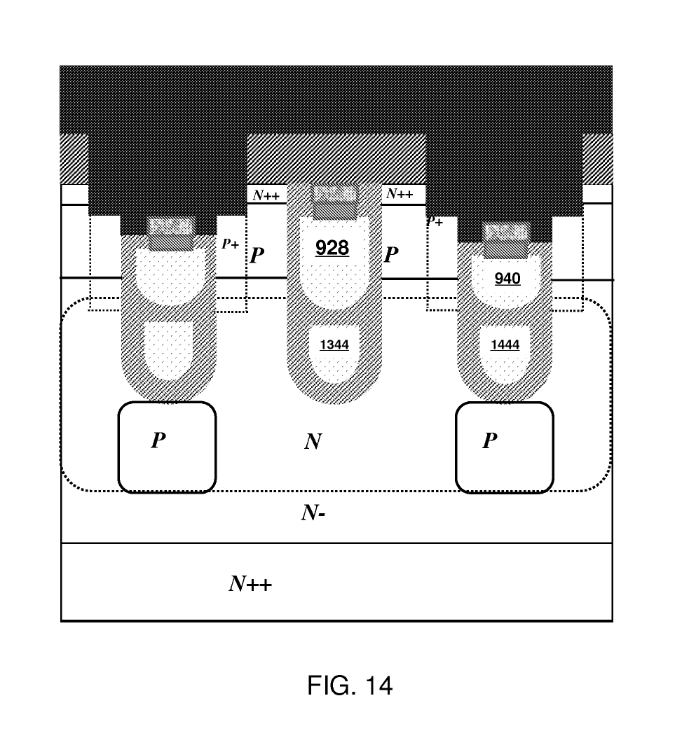

FIG. 14 shows yet another modification, in which the structure includes not only shield electrodes 1344 under the gate electrodes 928 but also additional shield electrodes 1444 under the field plates 940. Other features of this implementation can be the same as those in FIG. 9 or 11, and modifications and variations as discussed below can be performed on this embodiment as well as on the embodiments of FIGS. 9 and 11.

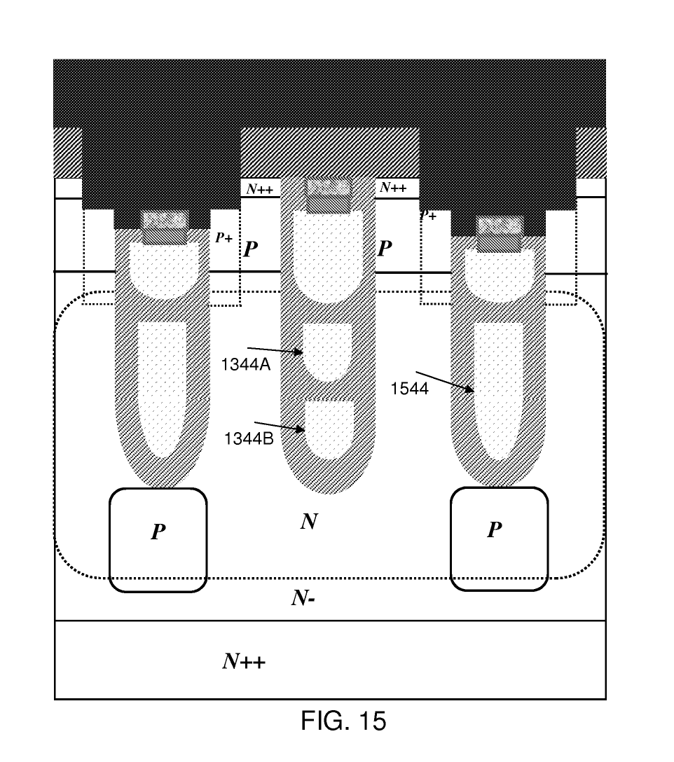

FIG. 15 shows yet another modification in which two shield electrodes are provided beneath the gate electrode. In this example the relative depth of the trenches is greater than that illustrated in FIG. 13. Thus the profile of the shield electrode 1544 has more vertical extent than that of field plate shield electrode 1444 in FIG. 14. Note also that two different shield electrodes 1344A and 1344B are provided beneath the gate electrode. This helps to smooth out the isopotential contours and thereby reduce peak electric field, according to well-known RESURF principles.

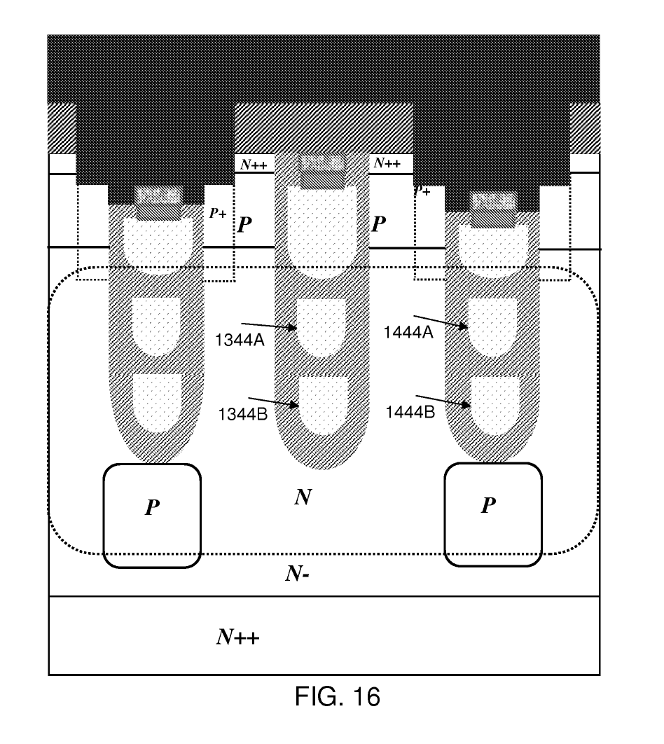

FIG. 16 shows yet another embodiment in which two different shield electrodes 1444A and 1444B are provided beneath the field plate electrodes, and two different shield electrodes 1344A and 1344B are also provided beneath the gate electrode.

According to some but not all embodiments, there is provided: Methods and systems for power semiconductor devices and structures with silicide cladding on both gates and field plates. Sidewall spacers, e.g. of silicon nitride, avoid lateral shorts or leakage between the gate silicide and the source region. A source metallization makes lateral contact to the shallow n++ source, and also makes contact to the field plate silicide and the p+ body contact region.

According to some but not all embodiments, there is provided: A process for fabricating a semiconductor device, comprising: etching trenches into a first-conductivity-type semiconductor material; insulating sidewalls of said trenches with a first dielectric material; forming gate electrodes in first ones of said trenches, and field plate electrodes in second ones of said trenches; said gate electrodes and field plate electrodes each comprising a semiconductor material which is not completely crystalline; forming a shallow first-conductivity-type source region, and a second-conductivity-type body region which is deeper than said first-conductivity-type source region, to thereby provide a body region which is capacitively coupled to said gate; forming sidewall filaments of a second dielectric material in both said first and second trenches; depositing a metal both onto portions of said gate electrode and also onto portions of said field plate electrode where exposed by said sidewall filaments, and at least partially reacting said material to form a conductive metal-semiconductor compound; etching recesses over said second trenches, and forming second-conductivity-type body contact regions; connecting said field plates together with said source region and said body contact region, at locations of said field plates; and connecting said source region, said gate electrode, and a backside connection to said first-conductivity-type material to provide external terminals for a field effect transistor.

According to some but not all embodiments, there is provided: A process for fabricating a semiconductor device, comprising: etching trenches into an n-type semiconductor material; insulating sidewalls of said trenches with a first dielectric material; forming gate electrodes in first ones of said trenches, and field plate electrodes in second ones of said trenches; said gate and field plate electrodes each comprising a semiconductor material which is not completely crystalline; forming a shallow n-type source region, and a p-type body region which is deeper than said n-type source region, to thereby provide a body region which is capacitively coupled to said gate; forming sidewall filaments of a second dielectric material in both said first and second trenches; depositing a metal both onto portions of said gate electrode and also onto portions of said field plate electrode where exposed by said sidewall filaments, and at least partially reacting said material to form a conductive metal-semiconductor compound; and etching recesses over said second trenches, and forming p-type body contact regions; connecting said field plates together with said source region and said body contact region, at locations of said field plates; and connecting said source region, said gate electrode, and a backside connection to said n-type material to provide external terminals for a field effect transistor.

According to some but not all embodiments, there is provided: A process for fabricating a semiconductor device, comprising: etching trenches into a first-conductivity-type semiconductor material; insulating sidewalls of said trenches with a first dielectric material; forming gate electrodes in first ones of said trenches, and field plate electrodes with one or more underlying shield electrodes in second ones of said trenches; said gate electrodes and field plate electrodes each comprising a semiconductor material which is not completely crystalline; forming a shallow first-conductivity-type source region, and a second-conductivity-type body region which is deeper than said first-conductivity-type source region, to thereby provide a body region which is capacitively coupled to said gate; forming sidewall filaments of a second dielectric material in both said first and second trenches; depositing a metal both onto portions of said gate electrode and also onto portions of said field plate electrode where exposed by said sidewall filaments, and at least partially reacting said material to form a conductive metal-semiconductor compound; etching recesses over said second trenches, and forming second-conductivity-type body contact regions; connecting said field plates together with said source region and said body contact region, at locations of said field plates; and connecting said source region, said gate electrode, and a backside connection to said first-conductivity-type material to provide external terminals for a field effect transistor.

According to some but not all embodiments, there is provided: A process for fabricating a semiconductor device, comprising: etching trenches into a first-conductivity-type semiconductor material; insulating sidewalls of said trenches with a first dielectric material; forming gate electrodes with one or more underlying shield electrodes in first ones of said trenches, and field plate electrodes in second ones of said trenches; said gate electrodes and field plate electrodes each comprising a semiconductor material which is not completely crystalline; forming a shallow first-conductivity-type source region, and a second-conductivity-type body region which is deeper than said first-conductivity-type source region, to thereby provide a body region which is capacitively coupled to said gate; forming sidewall filaments of a second dielectric material in both said first and second trenches; depositing a metal both onto portions of said gate electrode and also onto portions of said field plate electrode where exposed by said sidewall filaments, and at least partially reacting said material to form a conductive metal-semiconductor compound; etching recesses over said second trenches, and forming second-conductivity-type body contact regions; connecting said field plates together with said source region and said body contact region, at locations of said field plates; and connecting said source region, said gate electrode, and a backside connection to said first-conductivity-type material to provide external terminals for a field effect transistor.

According to some but not all embodiments, there is provided: A process for fabricating a semiconductor device, comprising: etching trenches into a first-conductivity-type semiconductor material; insulating sidewalls of said trenches with a first dielectric material; forming gate electrodes with one or more underlying shield electrodes in first ones of said trenches, and field plate electrodes with one or more underlying shield electrodes in second ones of said trenches; said gate electrodes and field plate electrodes each comprising a semiconductor material which is not completely crystalline; forming a shallow first-conductivity-type source region, and a second-conductivity-type body region which is deeper than said first-conductivity-type source region, to thereby provide a body region which is capacitively coupled to said gate; forming sidewall filaments of a second dielectric material in both said first and second trenches; depositing a metal both onto portions of said gate electrode and also onto portions of said field plate electrode where exposed by said sidewall filaments, and at least partially reacting said material to form a conductive metal-semiconductor compound; etching recesses over said second trenches, and forming second-conductivity-type body contact regions; connecting said field plates together with said source region and said body contact region, at locations of said field plates; and connecting said source region, said gate electrode, and a backside connection to said first-conductivity-type material to provide external terminals for a field effect transistor.

According to some but not all embodiments, there is provided: A device made by any of the above processes.

According to some but not all embodiments, there is provided: A semiconductor device comprising: a plurality of gate trenches, and a plurality of field plate trenches, wherein said gate trenches extend into a first-conductivity-type region of a semiconductor mass, wherein both said gate trenches and said field plate trenches penetrate through both a second-conductivity-type body region, and wherein ones of said gate and field plate trenches are laterally adjoined by a shallow heavily-doped first-conductivity-type source region, which generally lies above said body region; insulated gate electrodes which are inside but do not fill said gate trenches, and insulated conductive field plates which are inside but do not fill said field plate trenches; both said gate and field plate trenches being laterally insulated from said body region by a first insulating material; a cladding layer of conductive material, located atop said gate electrodes and atop said field plates, said cladding layer being laterally insulated from said first insulating material, and from said source region, by self-aligned spacers of a second insulating material; and metallization connected, atop said field plate trenches, to said cladding layer, to said source region, and to a heavily doped portion of said body region.

According to some but not all embodiments, there is provided: A semiconductor device comprising: a plurality of gate trenches, and a plurality of field plate trenches, wherein said gate trenches extend into an n-type epitaxial region of a semiconductor mass, wherein both said gate trenches and said field plate trenches penetrate through both a p-type body region, and wherein ones of said gate and field plate trenches are laterally adjoined by a shallow heavily-doped n-type source region, which generally lies above said body region; insulated gate electrodes which are inside but do not fill said gate trenches, and insulated conductive field plates which are inside but do not fill said field plate trenches; both said gate and field plate trenches being laterally insulated from said body region by a first insulating material; a cladding layer of conductive material, located atop said gate electrodes and atop said field plates, said cladding layer being laterally insulated from said first insulating material, and from said source region, by self-aligned spacers of a second insulating material; and metallization connected, atop said field plate trenches, to said cladding layer, to said source region, and to a heavily doped portion of said body region.

According to some but not all embodiments, there is provided: A power semiconductor device, comprising, in a semiconductor material: a first trench containing both a buried insulated gate electrode and also a first metallic cladding portion which overlies and is narrower than said gate electrode; a second trench containing both an insulated recessed field plate electrode and also a second metallic cladding portion which overlies and is narrower than said insulated recessed field plate electrode; wherein said metallic cladding portions have a composition which is different from both said gate electrode and said insulated recessed field plate electrode; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion over said field plate, and is also operatively connected to said body region; wherein said source metallization, said gate electrode, and a backside connection to said semiconductor material provide external terminals for a field effect transistor.

According to some but not all embodiments, there is provided: A power semiconductor device, comprising, in a semiconductor material: a first trench containing both a buried insulated gate electrode and also a first metallic cladding portion which overlies and is narrower than said gate electrode; a second trench containing both an insulated recessed field plate electrode and also a second metallic cladding portion which overlies and is narrower than said insulated recessed field plate electrode; wherein said metallic cladding portions have a composition which is different from both said gate electrode and said insulated recessed field plate electrode; wherein said insulated gate electrode and said insulated recessed field plate electrode are both formed in a common thin film deposition step; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion over said field plate, and is also operatively connected to said body region; wherein said source metallization, said gate electrode, and a backside connection to said semiconductor material provide external terminals for a field effect transistor.

According to some but not all embodiments, there is provided: A power semiconductor device, comprising, in a semiconductor material: a first trench containing both a buried insulated gate electrode and also a first metallic cladding portion which overlies and is narrower than said gate electrode; a second trench containing both an insulated recessed field plate electrode and also a second metallic cladding portion which overlies and is narrower than said insulated recessed field plate electrode; wherein said metallic cladding portions have a composition which is different from both said gate electrode and said insulated recessed field plate electrode; wherein said insulated gate electrode and said insulated recessed field plate electrode are both made of the same material; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion over said field plate, and is also operatively connected to said body region; wherein said source metallization, said gate electrode, and a backside connection to said semiconductor material provide external terminals for a field effect transistor.

According to some but not all embodiments, there is provided: A power semiconductor device, comprising, in a semiconductor material: a first trench containing both a buried insulated gate electrode and also a first metallic cladding portion which overlies and is narrower than said gate electrode; a second trench containing both an insulated recessed field plate electrode and also a second metallic cladding portion which overlies and is narrower than said insulated recessed field plate electrode; wherein said metallic cladding portions have a composition which is different from both said gate electrode and said insulated recessed field plate electrode; wherein said insulated gate electrode and said insulated recessed field plate electrode are both made of a polycrystalline semiconductor material; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion over said field plate, and is also operatively connected to said body region; wherein said source metallization, said gate electrode, and a backside connection to said semiconductor material provide external terminals for a field effect transistor.

According to some but not all embodiments, there is provided: A power semiconductor device, comprising, in a semiconductor material: a first trench containing both a buried insulated gate electrode and also a first metallic cladding portion which overlies and is narrower than said gate electrode; a second trench containing both an insulated recessed field plate electrode and also a second metallic cladding portion which overlies and is narrower than said insulated recessed field plate electrode; wherein said metallic cladding portions have a composition which is different from both said gate electrode and said insulated recessed field plate electrode; wherein said metallic cladding portions are both in-situ reacted metal silicides; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion over said field plate, and is also operatively connected to said body region; wherein said source metallization, said gate electrode, and a backside connection to said semiconductor material provide external terminals for a field effect transistor.

According to some but not all embodiments, there is provided: A power semiconductor device, comprising, in a semiconductor material: a first trench containing both a buried insulated gate electrode and also a first metallic cladding portion which overlies and is narrower than said gate electrode; a second trench containing both an insulated recessed field plate electrode and also a second metallic cladding portion which overlies and is narrower than said insulated recessed field plate electrode; wherein said metallic cladding portions have a composition which is different from both said gate electrode and said insulated recessed field plate electrode; wherein said metallic cladding portions are both portions of a single thin-film layer; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion over said field plate, and is also operatively connected to said body region; wherein said source metallization, said gate electrode, and a backside connection to said semiconductor material provide external terminals for a field effect transistor.

According to some but not all embodiments, there is provided: A power semiconductor device, comprising, in a semiconductor material: a first trench containing both a buried insulated gate electrode and also a first metallic cladding portion which overlies and is narrower than said gate electrode; a second trench containing both an insulated recessed field plate electrode and also a second metallic cladding portion which overlies and is narrower than said insulated recessed field plate electrode; wherein said metallic cladding portions have a composition which is different from both said gate electrode and said insulated recessed field plate electrode; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion over said field plate, and is also operatively connected to said body region; wherein said source metallization, said gate electrode, and a backside connection to said semiconductor material provide external terminals for a field effect transistor; and wherein said second trench, but not said first trench, has an additional doping component below the bottom thereof.

According to some but not all embodiments, there is provided: A power semiconductor device, comprising, in a semiconductor material: a first trench containing both a buried insulated gate electrode and also a first metallic cladding portion which is narrower than, and at least partly recessed into the surface of, said gate electrode; a second trench containing both an insulated recessed field plate electrode and also a second metallic cladding portion which is narrower than, and at least partly recessed into the surface of, said insulated recessed field plate electrode; wherein said metallic cladding portions have a composition which is different from both said gate electrode and said insulated recessed field plate electrode; a shallow first-conductivity-type source region, and a second-conductivity-type body region which is deeper than said first-conductivity-type source region, and which is capacitively coupled to said gate electrode; and a source metallization layer which makes lateral contact to said source region, and makes a vertical contact to said cladding portion recessed in said field plate, and is also operatively connected to said body region; wherein said source metallization, said gate electrode, and a backside connection to said semiconductor material provide external terminals for a field effect transistor.

According to some but not all embodiments, there is provided: A power semiconductor device, comprising, in a semiconductor material: a first trench containing both a buried insulated gate electrode and also a metallic cladding portion which is narrower than, and at least partly recessed into the surface of, said gate electrode; a second trench containing an insulated embedded field plate electrode; wherein said metallic cladding portion has a composition which is different from both said gate electrode and said insulated embedded field plate electrode; a shallow first-conductivity-type source region, and a second-conductivity-type body region which is deeper than said first-conductivity-type source region, and which is capacitively coupled to said gate electrode; and a source metallization layer which makes lateral contact to said source region, and is also operatively connected to said body region; wherein said source metallization, said gate electrode, and a backside connection to said semiconductor material provide external terminals for a field effect transistor.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

Other metals can optionally be used for silicidation, and a wide range of suitable metals have been proposed in the literature. Examples of these include Co, Ni, and many others.

After silicidation has been performed, the SiN spacer can be retained or optionally can be etched away.

If the SiN spacer has been etched away, it can optionally be replaced with a grown oxide.

In one alternative embodiment in which some nonreacted metal is left inside the trench, the filling metal can be different from the siliciding metal.

In one such sample embodiment, the nonreacted siliciding metal is completely removed and the filling metal is subsequently deposited. Fabrication can then continue e.g. as from FIG. 10. This step can be performed after, or optionally before, silicidation is performed.

In e.g. the sample embodiment shown in FIG. 6, the total thickness of the insulator layer is e.g. 90 nm (10 nm of SiO₂+80 nm of SiN). In other sample embodiments, the total thickness of the insulator can be e.g. 25-250 nm, and can be adjusted based on the design optimization and process control as well as the gate-to-source reliability requirement.

The gate electrode can be a trench gate electrode with thick bottom oxide, or can optionally be a split gate electrode.

The field plates can be recessed field plates (RFP), or can optionally be embedded field plates (EFP).

The gate electrode and field plate electrodes can optionally be shielded by one or more shield electrodes.

Recessed silicidation, as seen in e.g. FIG. 1B, can optionally be combined with the structures and methods disclosed above.

The disclosed inventions can also be applied to active devices which use at least some bipolar conduction, e.g. IGBTs.

The semiconductor material can be silicon, or can optionally be

The figures provided are focused on the fabrication steps most relevant to forming a two-trench power device with silicided gate and/or field plate electrodes. Optionally, additional diodes, active devices, and/or small-signal devices can be included on the same die (semiconductor mass).

In alternative embodiments, it is also contemplated that the semiconductor material used does not have to be silicon, but can be gallium nitride, or Si_{0.9}Ge_{0.1}, or less preferably III-V semiconductors.

Of course additional implantation and/or patterning steps can be used if desired, and often will be, depending on particular process optimizations and requirements of other elements which may be present on the same die.

Preferably guard ring structures will be included surrounding the power device. A wide variety of guard ring structures can be used or not.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

Additional general background, which helps to show variations and implementations, as well as some features which can be synergistically with the inventions claimed below, may be found in the following US patents and applications. All of these applications have at least some common ownership, copendency, and inventorship with the present application, and all of them are hereby incorporated by reference: U.S. Pat. No. 8,076,719; U.S. Pat. No. 8,058,682; US 2008-0164516 A1; 7,964,913; US 2008-0164520 A1; US 2008-0166845 A1; U.S. Pat. No. 7,704,842; U.S. Pat. No. 7,923,804; U.S. Pat. No. 7,989,293; U.S. Pat. No. 7,910,439; U.S. Pat. No. 8,310,001; U.S. Pat. No. 7,911,021; US 2010-0025763 A1; US 2010-0308400 A1; US 2010-0025726 A1; 7,960,783; 8,304,329; US 2010-0219462 A1; US 2011-0079843 A1; US 2010-0327344 A1; US 2012-0043602 A1; U.S. Pat. No. 8,310,007; U.S. Pat. No. 8,310,006; US 2011-0039384 A1; US 2011-0169103 A1; U.S. Pat. No. 8,294,235; US 2011-0254088 A1; 8,203,180; US 2012-0161226 A1; US 2012-0098055 A1; US 2011-0298043 A1; US 2012-0098056 A1; US 2012-0032258 A1; US 2012-0261746 A1.

The claims as filed are intended to be as comprehensive as possible, and NO subject matter is intentionally relinquished, dedicated, or abandoned.

1. A process for fabricating a semiconductor device, comprising:
etching trenches into a first-conductivity-type semiconductor material;
insulating sidewalls of said trenches with a first dielectric material;
forming gate electrodes in first ones of said trenches, and field plate electrodes in second ones of said trenches;
said gate electrodes and field plate electrodes each comprising a semiconductor material which is not completely crystalline;
forming a shallow first-conductivity-type source region, and a second-conductivity-type body region which is deeper than said first-conductivity-type source region, to thereby provide a body region which is capacitively coupled to said gate;
forming sidewall filaments of a second dielectric material in both said first and second trenches;
depositing a metal both onto portions of said gate electrode and also onto portions of said field plate electrode where exposed by said sidewall filaments, and at least partially reacting said material to form a conductive metal-semiconductor compound;
etching recesses over said second trenches, and forming second-conductivity-type body contact regions;
connecting said field plates together with said source region and said body contact region, at locations of said field plates; and
connecting said source region, said gate electrode, and a backside connection to said first-conductivity-type material to provide external terminals for a field effect transistor.

2. The process of claim 1, wherein said first dielectric material is a silicon oxide.

3. The process of claim 1, wherein said first dielectric material is silicon dioxide.

4. The process of claim 1, wherein said semiconductor material is silicon.

5. The process of claim 1, wherein said polycrystalline semiconductor material is silicon.

6. The process of claim 1, wherein said first conductivity type is n type.

7. The process of claim 1, further comprising the step of removing at least some unreacted metal.

8. The process of claim 1, wherein said metal is titanium.

9. A process for fabricating a semiconductor device, comprising:
etching trenches into an n-type semiconductor material;
insulating sidewalls of said trenches with a first dielectric material;
forming gate electrodes in first ones of said trenches, and field plate electrodes in second ones of said trenches;
said gate and field plate electrodes each comprising a semiconductor material which is not completely crystalline;
forming a shallow n-type source region, and a p-type body region which is deeper than said n-type source region, to thereby provide a body region which is capacitively coupled to said gate;
forming sidewall filaments of a second dielectric material in both said first and second trenches;
depositing a metal both onto portions of said gate electrode and also onto portions of said field plate electrode where exposed by said sidewall filaments, and at least partially reacting said material to form a conductive metal-semiconductor compound; and
etching recesses over said second trenches, and forming p-type body contact regions;
connecting said field plates together with said source region and said body contact region, at locations of said field plates; and
connecting said source region, said gate electrode, and a backside connection to said n-type material to provide external terminals for a field effect transistor.

10. The process of claim 9, wherein said first dielectric material is a silicon oxide.

11. The process of claim 9, wherein said first dielectric material is silicon dioxide.

12. The process of claim 9, wherein said semiconductor material is silicon.

13. The process of claim 9, wherein said polycrystalline semiconductor material is silicon.

14. The process of claim 9, further comprising the step of removing at least some unreacted metal.

15. The process of claim 9, wherein said metal is titanium.

16. A process for fabricating a semiconductor device, comprising:
etching trenches into a first-conductivity-type semiconductor material;
insulating sidewalls of said trenches with a first dielectric material;
forming gate electrodes in first ones of said trenches, and field plate electrodes with one or more underlying shield electrodes in second ones of said trenches;
said gate electrodes and field plate electrodes each comprising a semiconductor material which is not completely crystalline;
forming a shallow first-conductivity-type source region, and a second-conductivity-type body region which is deeper than said first-conductivity-type source region, to thereby provide a body region which is capacitively coupled to said gate;
forming sidewall filaments of a second dielectric material in both said first and second trenches;
depositing a metal both onto portions of said gate electrode and also onto portions of said field plate electrode where exposed by said sidewall filaments, and at least partially reacting said material to form a conductive metal-semiconductor compound;
etching recesses over said second trenches, and forming second-conductivity-type body contact regions;
connecting said field plates together with said source region and said body contact region, at locations of said field plates; and
connecting said source region, said gate electrode, and a backside connection to said first-conductivity-type material to provide external terminals for a field effect transistor.

17. The process of claim 16, wherein said first dielectric material is a silicon oxide.

18. The process of claim 16, wherein said first dielectric material is silicon dioxide.

19. The process of claim 16, wherein said semiconductor material is silicon.

20. The process of claim 16, wherein said polycrystalline semiconductor material is silicon.

21-105. (canceled)
